(19) United States
(12) Patent Application Publication
(10) Pub. No.: US 2010/0307418 A1
(43) Pub. Date: Dec. 9, 2010

(54) VAPOR PHASE EPITAXY APPARATUS OF GROUP III NITRIDE SEMICONDUCTOR

(75) Inventors: Kenji ISO, Kanagawa (JP); Yoshiyasu ISHIHAMA, Kanagawa (JP); Ryohei TAKAKI, Kanagawa (JP); Yuzuru TAKAHASHI, Kanagawa (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: JAPAN PIONICS., LTD.

(21) Appl. No.: 12/791,375

(22) Filed: Jun. 1, 2010

(30) Foreign Application Priority Data
Jun. 9, 2009 (JP) 2009-138586

(51) Int. Cl. H01L 21/205

(52) U.S. Cl. 118/725; 257/E21.102

(57) ABSTRACT

Provided is a vapor phase epitaxy apparatus of a group III nitride semiconductor capable of improving the uniformity of the film thickness distribution, and reaction rate, of a semiconductor. The vapor phase epitaxy apparatus of a group III nitride semiconductor includes: a susceptor for holding a substrate; the opposite face of the susceptor; a heater for heating the substrate; a reactor formed of a gap between the susceptor and the opposite face of the susceptor; a raw material gas-introducing portion for supplying a raw material gas to the reactor; and a reacted gas-discharging portion. In the vapor phase epitaxy apparatus of a group III nitride semiconductor, the raw material gas-introducing portion includes a first mixed gas ejection orifice capable of ejecting a mixed gas obtained by mixing three kinds, i.e., ammonia, an organometallic compound, and a carrier gas at an arbitrary ratio, and a second mixed gas ejection orifice capable of ejecting a mixed gas obtained by mixing two or three kinds selected from ammonia, the organometallic compound, and the carrier gas at an arbitrary ratio.

### TECHNICAL FIELD

The present invention relates to a vapor phase epitaxy apparatus (MOCVD apparatus) for a group III nitride semiconductor, and more specifically, to a vapor phase epitaxy apparatus for a group III nitride semiconductor including a susceptor for holding a substrate, a heater for heating the substrate, a raw material gas-introducing portion, a reactor, and a reacted gas-discharging portion.

### BACKGROUND ART

A metal organic chemical vapor deposition method (MOCVD method) has been employed for the crystal growth of a nitride semiconductor as frequently as a molecular beam epitaxy method (MBE method). In particular, the MOCVD method has been widely employed in apparatuses for the mass production of compound semiconductors in the industrial community because the method provides a higher crystal growth rate than the MBE method does and obviates the need for a high-vacuum apparatus or the like unlike the MBE method. In recent years, in association with widespread use of blue or ultraviolet LEDs and of blue or ultraviolet laser diodes, numerous researches have been conducted on increases in apertures and number of substrates each serving as an object of the MOCVD method in order that the mass productivity of gallium nitride, gallium indium nitride, and gallium aluminum nitride may be improved.

Such vapor phase epitaxy apparatuses are, for example, vapor phase epitaxy apparatuses each having a susceptor for holding a substrate, an opposite face of the susceptor, a heater for heating the substrate, a reactor formed of a gap between the susceptor and the opposite face of the susceptor, a raw material gas-introducing portion for providing the reactor with a raw material gas, and a reacted gas-discharging portion as described in Patent Documents 1 to 6. In addition, the following two kinds have been mainly proposed for the form of the vapor phase epitaxy apparatus. That is, a form in which a crystal growth surface is directed upward (face-up type) and a form in which a crystal growth surface is directed downward (face-down type) have been proposed. In the vapor phase epitaxy apparatus of each form, a substrate is installed horizontally and a raw material gas is introduced from a lateral direction of the substrate.

[Patent Document 1] JP 11-354456 A

[Patent Document 2] JP 2002-246323 A

[Patent Document 3] JP 2004-63555 A

[Patent Document 4] JP 2006-70325 A

[Patent Document 5] JP 2007-96280 A

[Patent Document 6] JP 2007-243060 A

### DISCLOSURE OF THE INVENTION

### Problems to be Solved by the Invention

An organometallic compound gas as a raw material for a group III metal and ammonia as a nitrogen source have been generally used as raw material gases for a group III nitride semiconductor. Those raw material gases are introduced from bombs for raw materials and the like into a reactor through tubes independent of each other with their flow rates each adjusted by a massflow controller. For example, Patent Document 4 discloses that, with regard to a face-down type vapor phase epitaxy apparatus, an organometallic compound and ammonia as raw materials are mixed immediately in front of a substrate in a reactor before being used in a reaction.

When the organometallic compound and ammonia are mixed immediately in front of the substrate as described above, however, these raw material gases are not sufficiently mixed even on the surface of the substrate, and hence it becomes difficult to perform crystal growth over the entirety of the substrate uniformly. In view of the foregoing, the following vapor phase epitaxy apparatus has been proposed in, for example, Patent Document 3. In the vapor phase epitaxy apparatus described in the document, a gas channel is designed so that ammonia and an organometallic compound may be mixed in advance before being supplied to a reactor and the mixed gas may be supplied to a substrate. However, even the invention has not solved the following problem. That is, the growth reaction rate of a crystal is slow when crystal growth is performed.

Vapor phase epitaxy apparatuses are mainly used in crystal growth for LED's, ultraviolet laser diodes, or electronic devices. In addition, as described above, the apertures of substrates serving as objects of the crystal growth have been increasing in recent years in order that the productivity of the crystal growth may be improved. However, an increase in size of each of the substrates involves the following problem. That is, the growth reaction rate of a group III nitride semiconductor on the substrate slows down and the uniformity of a crystalline film thickness distribution in the surface of the substrate deteriorates.

In addition, another problem arises. That is, the number of channels for the selection of gas flow rate conditions for crystal growth is small. In recent years, group III nitride semiconductors have shown remarkable development, and their crystal structures have become more and more complicated because additionally good performance has been requested. For example, a blue LED formed of the simplest structure is formed of n-type GaN, InGaN, GaN, AlGaN, and p-type GaN. In addition, a superlattice structure has also been frequently used in recent years for the purpose of additionally increasing the output of an LED. Raw material gas conditions for obtaining crystals each having good film quality vary in those various layers, and the flow rate of a raw material gas is optimized in each layer. As described above, however, one introducing tube is provided for each of ammonia and an organometallic compound in a vapor phase epitaxy apparatus that has been conventionally well known, and hence the optimization of a gas flow rate is largely restricted. In other words, an optimum condition has been determined by changing the absolute value of the flow rate of each of ammonia and the organometallic compound. However, it is hard to say that each layer grows under an optimum condition by such method in which the number of selection channels is small.

Therefore, a problem to be solved by the present invention is to provide a vapor phase epitaxy apparatus which: can realize a high growth reaction rate of a group III nitride semiconductor on a substrate and a good crystalline film thickness distribution in the surface of the substrate (film thickness uniformity); and has a large number of channels for the selection of raw material gas flow rate conditions.

### Means for Solving the Problems

The inventors of the present invention have made various studies with a view to obtaining a vapor phase epitaxy apparatus capable of growing a group III nitride semiconductor with good reaction efficiency in view of such circumstances. As a result, the inventors have found such a fact as described below. When a vapor phase epitaxy reactor is constituted so as to include a first mixed gas ejection orifice capable of ejecting a mixed gas obtained by mixing three kinds, i.e., ammonia, an organometallic compound, and a carrier gas at an arbitrary ratio, and a second mixed gas ejection orifice capable of ejecting two or three kinds selected from ammonia, the organometallic compound, and the carrier gas at an arbitrary ratio, optimum conditions for respective layers such as GaN, InGaN, and AlGaN can be easily controlled, and as a result, a high crystal growth rate and a good crystalline film thickness distribution in a surface can be obtained. Thus, the inventors have reached a vapor phase epitaxy apparatus of a group III nitride semiconductor of the present invention.

That is, the present invention is a vapor phase epitaxy apparatus of a group III nitride semiconductor, the apparatus having: a susceptor for holding a substrate; an opposite face of the susceptor; a heater for heating the substrate; a reactor formed of a gap between the susceptor and the opposite face of the susceptor; a raw material gas-introducing portion for supplying a raw material gas to the reactor; and a reacted gas-discharging portion, in which the raw material gas-introducing portion includes a first mixed gas ejection orifice capable of ejecting a mixed gas obtained by mixing three kinds, i.e., ammonia, an organometallic compound, and a carrier gas at an arbitrary ratio, and a second mixed gas ejection orifice capable of ejecting two or three kinds selected from ammonia, the organometallic compound, and the carrier gas at an arbitrary ratio.

### EFFECT OF THE INVENTION

The vapor phase epitaxy apparatus of the present invention is constituted so as to include the first mixed gas ejection orifice capable of ejecting the mixed gas obtained by mixing three kinds, i.e., ammonia, the organometallic compound, and the carrier gas at an arbitrary ratio, and the second mixed gas ejection orifice capable of supplying two or three kinds selected from ammonia, the organometallic compound, and the carrier gas at an arbitrary ratio to the reactor. As a result, the mixed gas in which the flow rate and concentration of each gas are optimally controlled can be supplied from each of the first mixed gas ejection orifice and the second mixed gas ejection orifice (which may hereinafter be abbreviated as “mixed gas ejection orifices”) to the surface of the substrate in the reactor, and optimum conditions can be easily controlled upon crystal growth of the respective layers such as GaN, InGaN, and AlGaN. Accordingly, the uniformity of the film thickness distribution, and reaction rate, of the group III nitride semiconductor can be improved.

### BRIEF DESCRIPTION OF THE DRAWINGS

FIG. 1 is a vertical sectional view illustrating an example of a vapor phase epitaxy apparatus of the present invention.

FIG. 2 is a vertical sectional view illustrating an example of the vapor phase epitaxy apparatus of the present invention.

FIG. 3 is an enlarged sectional view illustrating an example of the vicinity of a raw material gas-introducing portion of the vapor phase epitaxy apparatus of the present invention.

FIG. 4 is an enlarged sectional view illustrating an example of the vicinity of the raw material gas-introducing portion of the vapor phase epitaxy apparatus of the present invention.

FIG. 5 is an enlarged sectional view illustrating an example of the vicinity of the raw material gas-introducing portion of the vapor phase epitaxy apparatus of the present invention.

FIG. 6 is an enlarged sectional view illustrating an example of the vicinity of the raw material gas-introducing portion of the vapor phase epitaxy apparatus of the present invention.

FIG. 7 is a plan view illustrating an example of the form of a susceptor in the vapor phase epitaxy apparatus of the present invention.

FIG. 8 is a graph illustrating the thickness distribution of a GaN film in the surface of a 3-inch substrate (growth rate) in each of Examples 1 and 2, and Comparative Example 1.

FIG. 9 is a schematic view illustrating an example of the form of a gas-introducing tube in the vapor phase epitaxy apparatus of the present invention.

### DESCRIPTION OF SYMBOLS

1 substrate
2 susceptor
3 opposite face of susceptor
4 heater
5 reactor
6 raw material gas-introducing portion
7 reacted gas-discharging portion
8 mixed gas ejection orifice
9 soaking plate
10 disk for rotating susceptor
11 susceptor-rotating shaft
12 channel for gas containing ammonia
13 channel for gas containing organometallic compound
14 channel for carrier gas
15 channel for gas containing organometallic compound and carrier gas
16 channel for mixed gas
17 carrier gas ejection orifice
18 channel for coolant
19 claw
20 vapor phase epitaxy apparatus
21 tube for gas containing ammonia
22 tube for gas containing organometallic compound
23 tube for carrier gas
24 massflow controller

### BEST MODE FOR CARRYING OUT THE INVENTION

The present invention is applied to a vapor phase epitaxy apparatus for a group III nitride semiconductor having a susceptor for holding a substrate, an opposite face of the susceptor, a heater for heating the substrate, a reactor formed of a gap between the susceptor and the opposite face of the susceptor, a raw material gas-introducing portion for providing the reactor with a raw material gas, and a reacted gas-discharging portion. The vapor phase epitaxy apparatus of the present invention is a vapor phase epitaxy apparatus for performing the crystal growth of a nitride semiconductor mainly formed of a compound of one kind or two or more kinds of metals selected from gallium, indium, and aluminum, and nitrogen. In the present invention, an effect can be sufficiently exerted particularly in the case of such vapor phase epitaxy that a plurality of substrates of such sizes as to have diameters of 3 inches or more are held.

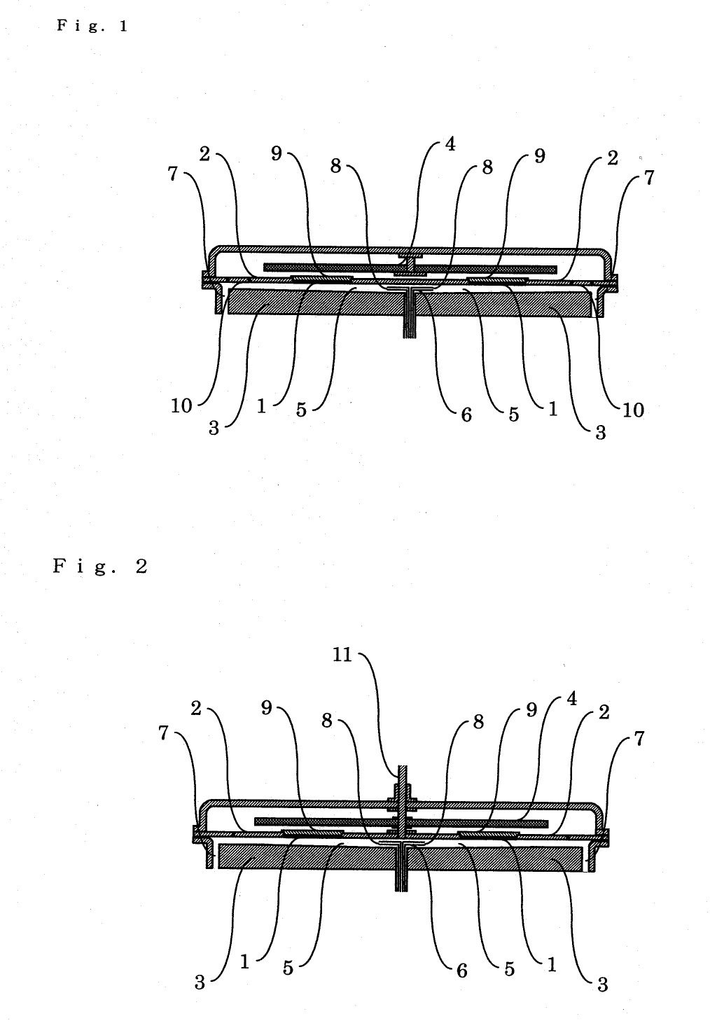

Hereinafter, the vapor phase epitaxy apparatus of the present invention is described in detail with reference to FIGS. 1 to 9. However, the present invention is not limited by the figures.

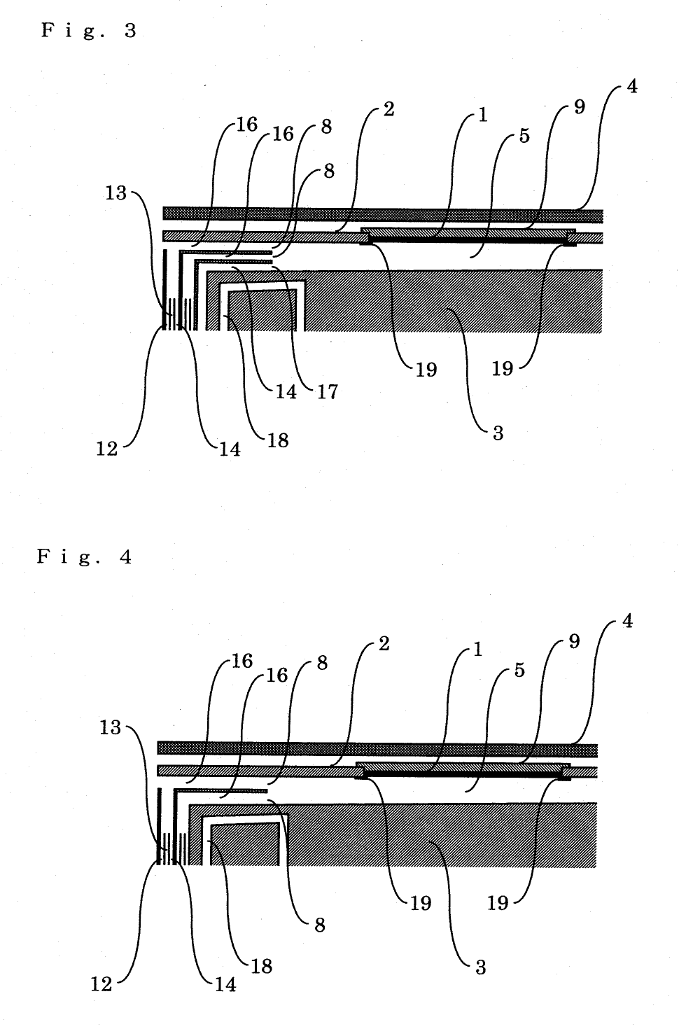

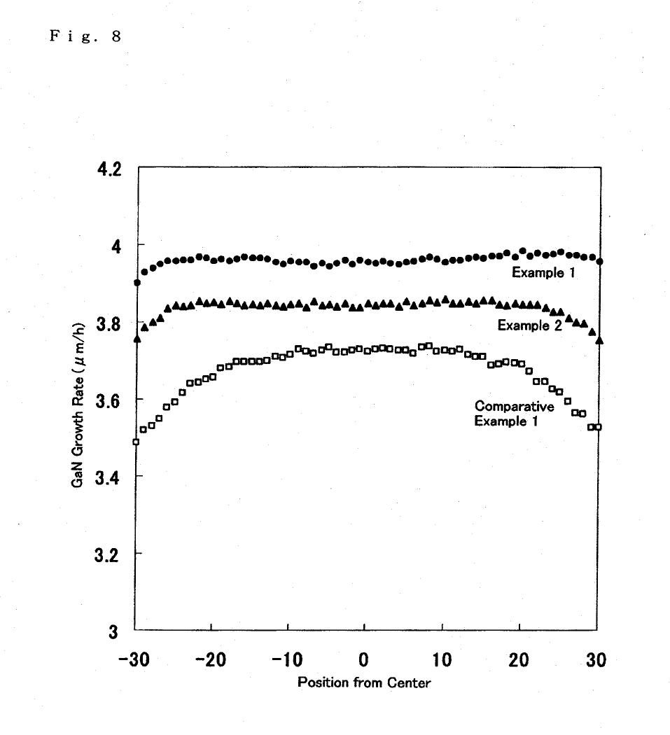

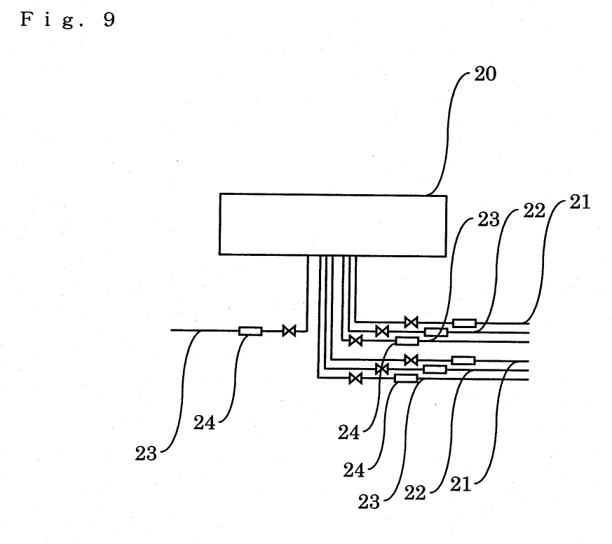

It should be noted that FIGS. 1 and 2 are each a vertical sectional view illustrating an example of the vapor phase epitaxy apparatus of the present invention (FIG. 1 illustrates a vapor phase epitaxy apparatus having such a mechanism that disks 10 are rotated to rotate a susceptor 2 and FIG. 2 illustrates a vapor phase epitaxy apparatus having such a mechanism that a susceptor-rotating shaft 11 is rotated to rotate the susceptor 2). FIGS. 3 to 6 are each an enlarged sectional view illustrating an example of the vicinity of the raw material gas-introducing portion of the vapor phase epitaxy apparatus of the present invention. FIG. 7 is a plan view illustrating an example of the form of the susceptor in the vapor phase epitaxy apparatus of the present invention. FIG. 8 is a graph illustrating the thickness distribution of a GaN film in the surface of a 3-inch substrate (growth rate) in each of Examples 1 and 2, and Comparative Example 1. FIG. 9 is a schematic view illustrating an example of the form of a gas-introducing tube in the vapor phase epitaxy apparatus of the present invention.

As illustrated in each of FIGS. 1 and 2, the vapor phase epitaxy apparatus of a group III nitride semiconductor of the present invention is a vapor phase epitaxy apparatus of a group III nitride semiconductor having: a susceptor 2 for holding a substrate 1; an opposite face 3 of the susceptor; a heater 4 for heating the substrate; a reactor 5 formed of a gap between the susceptor and the opposite face of the susceptor; a raw material gas-introducing portion 6 for supplying a raw material gas to the reactor; and a reacted gas-discharging portion 7. In addition, as illustrated in each of FIGS. 3 to 6, the vapor phase epitaxy apparatus of a group III nitride semiconductor is such that the raw material gas-introducing portion includes mixed gas ejection orifices 8 each capable of ejecting ammonia, an organometallic compound, and a carrier gas at an arbitrary ratio.

Here, the first mixed gas ejection orifice and the second mixed gas ejection orifice described above are the ejection orifices of channels for mixed gases of two types independent of each other, and are of constitutions different from such constitutions that mixed gases of the same type are ejected from two ejection orifices.

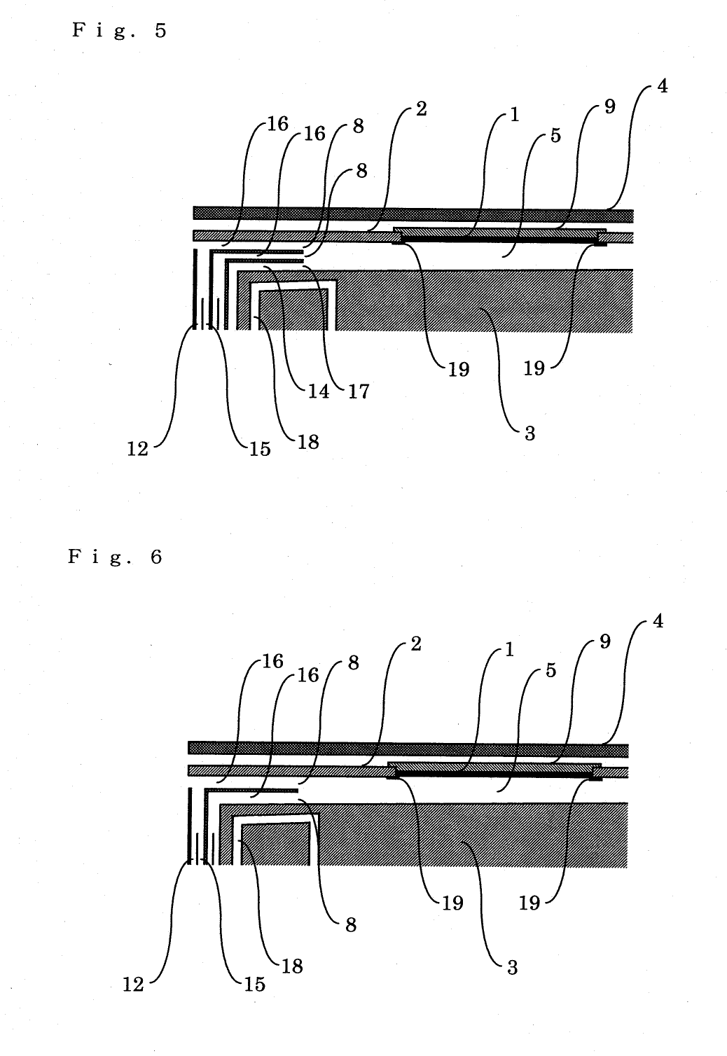

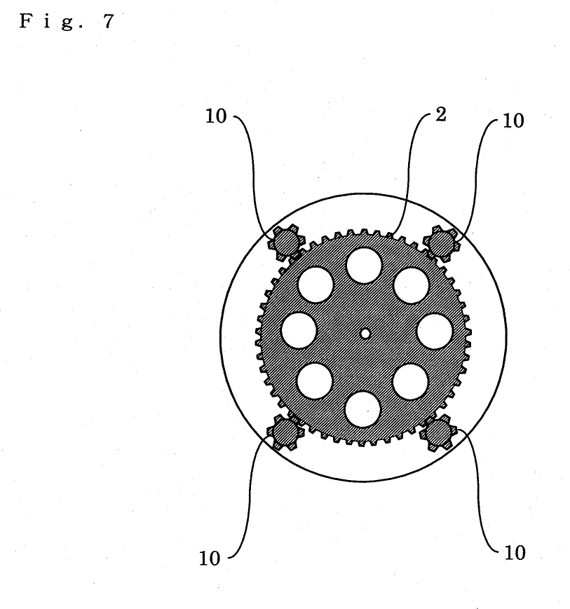

For example, the raw material gas-introducing portion 6 illustrated in each of FIGS. 3 and 4 is constituted as described below. That is, the portion has the two mixed gas ejection orifices 8, and a channel 12 for a gas containing ammonia, a channel 13 for a gas containing the organometallic compound, and a channel 14 for the carrier gas merge with one another in front of each mixed gas ejection orifice 8, and then the resultant is connected to a channel 16 for a mixed gas having the ejection orifice at its tip. In addition, the raw material gas-introducing portion illustrated in each of FIGS. 5 and 6 is constituted as described below. That is, the portion has the two mixed gas ejection orifices 8, and the channel 12 for a gas containing ammonia and a channel 15 for a gas containing the organometallic compound and the carrier gas merge with each other in front of each mixed gas ejection orifice 8, and then the resultant is connected to the channel 16 for a mixed gas having the ejection orifice at its tip.

It should be noted that, in the raw material gas-introducing portion of each of FIGS. 5 and 6, the gas containing the organometallic compound and the carrier gas can be mixed in advance at a desired mixing ratio outside the vapor phase epitaxy apparatus. Further, for example, the respective gas channels (channels 12 to 14) of each of FIGS. 3 and 4 are constituted as illustrated in FIG. 9. That is, tubes (a tube 21 for the gas containing ammonia, a tube 22 for the gas containing the organometallic compound, and a tube 23 for the carrier gas) are connected to the channels through, for example, massflow controllers 24 outside a vapor phase epitaxy apparatus 20 so that each gas can be supplied at a desired flow rate and a desired concentration. As described above, the vapor phase epitaxy apparatus of a group III nitride semiconductor of the present invention includes the two or more mixed gas ejection orifices 8 each capable of supplying each gas to the reactor while freely controlling the flow rate and concentration of the gas.

In the raw material gas-introducing portion 6, a portion where the raw material gases are mixed is typically set so as to be in front of the tip of each mixed gas ejection orifice 8 at a distance of 5 cm or more and 100 cm or less. In particular, a site where ammonia and the organometallic compound are mixed is constituted so as to be preferably in front of the tip of each mixed gas ejection orifice 8 at a distance of 5 cm or more and 100 cm or less, or more preferably in front of the tip of the mixed gas ejection orifice 8 at a distance of 10 cm or more and 50 cm or less. When the distance is shorter than 5 cm, the respective raw material gases may not be sufficiently mixed up to the tip of each mixed gas ejection orifice 8. In addition, when the distance is longer than 100 cm, adducts produced from the raw material gases may react with each other to an extent more than necessary. In addition, a diffusing plate or the like can also be used in the portion where the raw material gases are mixed for mixing the raw material gases effectively. It should be noted that, even when the portion where the gases are mixed is to be installed outside the vapor phase epitaxy apparatus in such case as described above, the portion where the gases are mixed can be regarded as part of the vapor phase epitaxy apparatus of the present invention.

In addition, the number of the mixed gas ejection orifices 8 in the raw material gas-introducing portion 6 is not limited to two, and any number of the ejection orifices may be used as long as the number is two or more. When an excessively large number of the ejection orifices are provided, however, an investigation on the optimization of the flow rate of a raw material gas requires a long time period. In addition, the structure of the raw material gas-introducing portion 6 becomes complicated. Even in the case where the number of the ejection orifices is four or more, influences on the growth rate of crystal growth and film thickness uniformity in the surface of the substrate remain nearly unchanged as compared with those in the case where the number of the ejection orifices is three. By reason of the foregoing, the number of the mixed gas ejection orifices 8 is preferably two or three. In the case where the number of the ejection orifices is three or more, a tube for a gas containing ammonia, a tube for a gas containing the organometallic compound, and a tube for the carrier gas are installed in the gas channels through respective massflow controllers as in the case where the number of the ejection orifices is two.

Further, as illustrated in each of FIGS. 3 and 5, a carrier gas ejection orifice 17 that supplies the carrier gas alone to the reactor as well as the first mixed gas ejection orifice capable of ejecting a mixed gas obtained by mixing three kinds, i.e., ammonia, the organometallic compound, and the carrier gas at an arbitrary ratio and the second mixed gas ejection orifice containing two or three kinds selected from ammonia, the organometallic compound, and the carrier gas can be provided in the raw material gas-introducing portion 6. When the carrier gas ejection orifice 17 is provided, the ejection orifice is typically provided on the side of the opposite face 3 of the susceptor. In addition, the number of the carrier gas ejection orifice 17 that supplies the carrier gas alone to the reactor is typically one. As in the case of the foregoing, the tube 23 for the carrier gas is installed in the channel 14 for the carrier gas in communication with the carrier gas ejection orifice 17 through the massflow controller 24.

The gas ejection orifices (the mixed gas ejection orifices 8 or the mixed gas ejection orifices 8 and the carrier gas ejection orifice 17) can be sequentially provided in a vertical direction. As illustrated in each of FIGS. 3 to 6, the mixed gas ejection orifices 8 and the carrier gas ejection orifice 17 are each constituted so as to be capable of ejecting a gas substantially horizontally to the substrate. The direction in which a gas is ejected from each of the mixed gas ejection orifices 8 and the carrier gas ejection orifice 17 is not needed to be completely horizontal to the substrate. When the gases are each ejected in a direction largely deviating from the horizontal direction, however, the gases do not become laminar flows, but are apt to become convection in the reactor. Accordingly, an angle θ of the ejection direction of each mixed gas ejection orifice 8 relative to the substrate preferably falls within the range of −10°<θ<10°.

The raw material gas-introducing portion 6 in the present invention is preferably provided with means (equipment) for cooling each of the mixed gas ejection orifices 8 and the carrier gas ejection orifice 17. In the vapor phase epitaxy of a group III nitride semiconductor, the inside of the reactor is typically heated to about 700° C. to about 1200° C. for crystal growth. Accordingly, the temperature of the raw material gas-introducing portion 6 also increases to about 600° C. to about 1100° C. unless cooling is performed. As a result, the raw material gases decompose in the raw material gas-introducing portion 6. In order that the decomposition may be suppressed, as illustrated in each of FIGS. 3 to 6, a channel 18 for a coolant is provided in, for example, a constituent near the raw material gas-introducing portion 6, and the coolant is flowed through the channel. Thus, the cooling is performed. For example, when the cooling is performed with water at about 30° C., the temperature of the raw material gas-introducing portion 6 can be reduced to about 200° C. to about 700° C. The above cooling means is more preferably provided near each mixed gas introduction ejection orifice 8.

However, a method of cooling each mixed gas ejection orifice 8 is not limited to such means as described above. That is, a method involving providing the cooling means for the uppermost portion of the raw material gas-introducing portion 6 or a method involving partially bonding the respective sites of the raw material gas-introducing portion 6 with a member having good thermal conductivity and providing the cooling means for one site of the raw material gas-introducing portion 6 to perform the cooling so that all members of the raw material gas-introducing portion 6 may be indirectly cooled is also permitted instead of the method involving providing the cooling means for the lowermost portion of the raw material gas-introducing portion 6 as illustrated in each of FIGS. 3 to 6.

It should be noted that the form of the susceptor 2 in the present invention is, for example, a disk shape having spaces for holding a plurality of substrates in its peripheral portion as illustrated in FIG. 7. Such vapor phase epitaxy apparatus as illustrated in FIG. 1 is of the following constitution. That is, a plurality of disks 10 for rotating the susceptor each having teeth on its outer periphery are installed so as to engage with teeth on the outer periphery of the susceptor 2, and the disks 10 for rotating the susceptor are rotated through external rotation-generating portions so that the susceptor 2 may rotate. The susceptor 2 is caused to hold the substrate 1 with a claw 19 together with a soaking plate 9, and is set in the vapor phase epitaxy apparatus so that the crystal growth surface of the substrate 1 may be directed, for example, downward.

Upon performance of crystal growth on the substrate with the vapor phase epitaxy apparatus of the present invention, the organometallic compound (such as trimethyl gallium, triethyl gallium, trimethyl indium, triethyl indium, trimethyl aluminum, or triethyl aluminum, or a mixed gas of them) and ammonia serving as the raw material gases, and the carrier gas (hydrogen or an inert gas such as nitrogen, or a mixed gas of them) are supplied by the respective external tubes to the raw material gas-introducing portion 6 of such vapor phase epitaxy apparatus of the present invention as described above. Further, the gases are each supplied from the raw material gas-introducing portion 6 to the reactor 5 under substantially optimum flow rate and concentration conditions.

### EXAMPLES

Next, the present invention is described specifically by way of examples. However, the present invention is not limited by these examples.

### Example 1

### Production of Vapor Phase Epitaxy Apparatus

Such a vapor phase epitaxy apparatus as illustrated in FIG. 1 was produced by providing, in a reaction vessel made of stainless steel, a disk-like susceptor (made of SiC-coated carbon, having a diameter of 600 mm and a thickness of 20 mm, and capable of holding eight 3-inch substrates), the opposite face (made of carbon) of the susceptor provided with a flow channel for flowing a coolant at a site corresponding to the vicinity of a raw material gas-introducing portion, a heater, a raw material gas-introducing portion (made of carbon), a reacted gas-discharging portion, and the like. In addition, eight substrates each formed of 3 inch-size sapphire (C surface) were set in the vapor phase epitaxy apparatus.

It should be noted that the raw material gas-introducing portion was of such a constitution as illustrated in FIG. 3. A horizontal distance between the tip of each mixed gas ejection orifice and a substrate was 34 mm, and the position at which ammonia, an organometallic compound, and a carrier gas were mixed was a site in front of the tip of each mixed gas ejection orifice at a distance of 50 cm. Further, a tube was connected to each gas channel of the raw material gas-introducing portion through, for example, a massflow controller outside the vapor phase epitaxy apparatus so that each gas could be supplied at a desired flow rate and a desired concentration.

(Vapor Phase Epitaxy Experiment)

Gallium nitride (GaN) was grown on the surfaces of the substrates with such vapor phase epitaxy apparatus. After the circulation of cooling water through the flow channel for flowing a coolant of the opposite face (flow rate: 18 L/min) had been initiated, each substrate was cleaned by increasing the temperature of the substrate to 1050° C. while flowing hydrogen. Subsequently, the temperature of each sapphire substrate was decreased to 510° C., and then a buffer layer formed of GaN was grown so as to have a thickness of about 20 nm on the substrate by using trimethyl gallium (TMG) and ammonia as raw material gases, and hydrogen as a carrier gas.

After the growth of the buffer layer, the supply of only TMG was stopped and the temperature was increased to 1050° C. After that, ammonia (flow rate: 30 L/min) and hydrogen (flow rate: 5 L/min) were supplied from the ejection orifice in an upper layer, TMG (flow rate: 40 cc/min), ammonia (flow rate: 10 L/min), and hydrogen (flow rate: 30 L/min) were supplied from the ejection orifice in a middle layer, and nitrogen (flow rate: 30 L/min) was supplied from the ejection orifice in a lower layer so that undoped GaN might be grown for 1 hour. It should be noted that all growth including that of the buffer layer was performed while each substrate was caused to rotate at a rate of 10 rpm.

After the nitride semiconductor had been grown as described above, the temperature was decreased, and then the substrates were taken out of the reaction vessel. After that, GaN thicknesses were measured. As a result, the GaN thickness at the center of each substrate was 3.95 μm. The foregoing shows that a GaN growth rate at the center of the substrate was 3.95 μm/h. In addition, FIG. 7 illustrates the thickness distribution of the GaN film in the surface of a 3-inch substrate in Example 1. It should be noted that the zero point in the axis of abscissa indicates the center of the substrate and any other value indicates a distance from the center. A fluctuation in film thickness in the surface was 1.8%. As described above, a crystal having a high crystal growth rate and a good crystalline film thickness distribution in a surface was obtained even in the 3-inch substrate.

### Example 2

Gallium nitride (GaN) was grown on the surfaces of the substrates with the same vapor phase epitaxy apparatus as in Example 1. After the circulation of cooling water through the flow channel for flowing a coolant of the opposite face (flow rate: 18 L/min) had been initiated, each substrate was cleaned by increasing the temperature of the substrate to 1050° C. while flowing hydrogen. Subsequently, the temperature of each sapphire substrate was decreased to 510° C., and then a buffer layer formed of GaN was grown so as to have a thickness of about 20 nm on the substrate by using trimethyl gallium (TMG) and ammonia as raw material gases, and hydrogen as a carrier gas.

After the growth of the buffer layer, the supply of only TMG was stopped and the temperature was increased to 1050° C. After that, ammonia (flow rate: 35 L/min) and hydrogen (flow rate: 5 L/min) were supplied from the ejection orifice in an upper layer, TMG (flow rate: 40 cc/min), ammonia (flow rate: 5 L/min), and hydrogen (flow rate: 30 L/min) were supplied from the ejection orifice in a middle layer, and nitrogen (flow rate: 30 L/min) was supplied from the ejection orifice in a lower layer so that undoped GaN might be grown for 1 hour. It should be noted that all growth including that of the buffer layer was performed while each substrate was caused to rotate at a rate of 10 rpm.

After the nitride semiconductor had been grown as described above, the temperature was decreased, and then the substrates were taken out of the reaction vessel. After that, GaN thicknesses were measured. As a result, the GaN thickness at the center of each substrate was 3.85 μm. The foregoing shows that a GaN growth rate at the center of the substrate was 3.85 μm/h. In addition, FIG. 7 illustrates the thickness distribution of the GaN film in the surface of a 3-inch substrate in Example 2. A fluctuation in film thickness in the surface was 1.8%. As described above, a crystal having a high crystal growth rate and a good crystalline film thickness distribution in a surface was obtained even in the 3-inch substrate.

### Example 3

A vapor phase epitaxy apparatus was produced in the same manner as in Example 1 except that the constitution of the raw material gas-introducing portion was changed to such a constitution as illustrated in FIG. 5 in the production of the vapor phase epitaxy apparatus of Example 1. A horizontal distance between the tip of each gas ejection orifice and a substrate, and the position at which ammonia, the organometallic compound, and the carrier gas were mixed were identical to those of Example 1. A vapor phase epitaxy experiment similar to that of Example 1 was performed with such vapor phase epitaxy apparatus.

After a nitride semiconductor had been grown, the temperature was reduced and each substrate was taken out of a reaction vessel. Then, the thickness of the GaN film was measured. As a result, the thickness of the GaN film at the center of each substrate, a GaN growth rate, the thickness distribution of the GaN film in the surface of a 3-inch substrate, and a fluctuation in film thickness in the surface were substantially identical to those of Example 1. As described above, a crystal having a high crystal growth rate and a good crystalline film thickness distribution in a surface was obtained even in the 3-inch substrate.

### Example 4

A vapor phase epitaxy apparatus was produced in the same manner as in Example 1 except that the constitution of the raw material gas-introducing portion was changed to such a constitution as illustrated in FIG. 5 in the production of the vapor phase epitaxy apparatus of Example 1. A horizontal distance between the tip of each gas ejection orifice and a substrate, and the position at which ammonia, the organometallic compound, and the carrier gas were mixed were identical to those of Example 1. A vapor phase epitaxy experiment similar to that of Example 2 was performed with such vapor phase epitaxy apparatus.

After a nitride semiconductor had been grown, the temperature was reduced and each substrate was taken out of a reaction vessel. Then, the thickness of the GaN film was measured. As a result, the thickness of the GaN film at the center of each substrate, a GaN growth rate, the thickness distribution of the GaN film in the surface of a 3-inch substrate, and a fluctuation in film thickness in the surface were substantially identical to those of Example 2. As described above, a crystal having a high crystal growth rate and a good crystalline film thickness distribution in a surface was obtained even in the 3-inch substrate.

### Comparative Example 1

### Production of Vapor Phase Epitaxy Apparatus

A vapor phase epitaxy apparatus was produced in the same manner as in Example 1 except that the ejection orifice in the upper layer was changed to an ejection orifice capable of ejecting ammonia and a carrier gas at an arbitrary ratio, the ejection orifice in the middle layer was changed to an ejection orifice capable of ejecting an organometallic compound and a carrier gas at an arbitrary ratio, and the ejection orifice in the lower layer was changed to an ejection orifice capable of ejecting a carrier gas in the production of the vapor phase epitaxy apparatus of Example 1. A horizontal distance between the tip of each gas ejection orifice and a substrate, and the position at which the respective gases were mixed were identical to those of Example 1.

(Vapor Phase Epitaxy Experiment)

Gallium nitride (GaN) was grown on the surfaces of the substrates with such vapor phase epitaxy apparatus. After the circulation of cooling water through the flow channel for flowing a coolant of the opposite face (flow rate: 18 L/min) had been initiated, each substrate was cleaned by increasing the temperature of the substrate to 1050° C. while flowing hydrogen. Subsequently, the temperature of each sapphire substrate was decreased to 510° C., and then a buffer layer formed of GaN was grown so as to have a thickness of about 20 nm on the substrate by using trimethyl gallium (TMG) and ammonia as raw material gases, and hydrogen as a carrier gas.

After the growth of the buffer layer, the supply of only TMG was stopped and the temperature was increased to 1050° C. After that, ammonia (flow rate: 40 L/min) and hydrogen (flow rate: 5 L/min) were supplied from the ejection orifice in an upper layer, TMG (flow rate: 40 cc/min) and hydrogen (flow rate: 30 L/min) were supplied from the ejection orifice in a middle layer, and nitrogen (flow rate: 30 L/min) was supplied from the ejection orifice in a lower layer so that undoped GaN might be grown for 1 hour. It should be noted that all growth including that of the buffer layer was performed while each substrate was caused to rotate at a rate of 10 rpm.

After the nitride semiconductor had been grown as described above, the temperature was decreased, and then the substrates were taken out of the reaction vessel. After that, GaN thicknesses were measured. As a result, the GaN thickness at the center of each substrate was 3.70 μm. The foregoing shows that a GaN growth rate at the center of the substrate was 3.70 μm/h. The value was smaller than the GaN growth rate of each of Example 1 and Example 2. In addition, FIG. 7 illustrates the thickness distribution of the GaN film in the surface of a 3-inch substrate in Comparative Example 1. A fluctuation in film thickness in the surface was 5.0%, and the thickness distribution in the surface was deteriorated compared to Examples 1 and 2.

As described above, the vapor phase epitaxy apparatus of the present invention can improve the uniformity of the film thickness distribution, and reaction rate, of a group III nitride semiconductor.

1. A vapor phase epitaxy apparatus of a group III nitride semiconductor, the apparatus comprising:
a susceptor for holding a substrate;
an opposite face of the susceptor;
a heater for heating the substrate;
a reactor formed of a gap between the susceptor and the opposite face of the susceptor;
a raw material gas-introducing portion for supplying a raw material gas to the reactor; and
a reacted gas-discharging portion,
wherein the raw material gas-introducing portion includes
a first mixed gas ejection orifice capable of ejecting a mixed gas obtained by mixing three kinds, i.e., ammonia, an organometallic compound, and a carrier gas at an arbitrary ratio, and
a second mixed gas ejection orifice capable of ejecting a mixed gas obtained by mixing two or three kinds selected from ammonia, the organometallic compound, and the carrier gas at an arbitrary ratio.

2. The vapor phase epitaxy apparatus of a group III nitride semiconductor according to claim 1, wherein the raw material gas-introducing portion includes a carrier gas ejection orifice that supplies the carrier gas alone to the reactor as well as the first mixed gas ejection orifice and the second mixed gas ejection orifice.

3. The vapor phase epitaxy apparatus of a group III nitride semiconductor according to claim 1, wherein the apparatus is constituted so that ammonia and the organometallic compound are mixed at a site in front of a tip of each of the first mixed gas ejection orifice and the second mixed gas ejection orifice at a distance of 5 cm or more and 100 cm or less.

4. The vapor phase epitaxy apparatus of a group III nitride semiconductor according to claim 1, wherein the first mixed gas ejection orifice and the second mixed gas ejection orifice are sequentially provided in a vertical direction.

5. The vapor phase epitaxy apparatus of a group III nitride semiconductor according to claim 1, wherein means for cooling the mixed gas is provided near each of the first mixed gas ejection orifice and the second mixed gas ejection orifice.

6. The vapor phase epitaxy apparatus of a group III nitride semiconductor according to claim 2, wherein means for cooling the carrier gas ejection orifice is provided.

7. The vapor phase epitaxy apparatus for a group III nitride semiconductor according to claim 1, wherein the nitride semiconductor comprises a compound of one kind or two or more kinds of metals selected from gallium, indium, and aluminum, and nitrogen.

8. The vapor phase epitaxy apparatus of a group III nitride semiconductor according to claim 1, wherein the substrate is held with its crystal growth surface directed downward.
